(19) United States
(12) Patent Application Publication
(10) Pub. No.: US 2017/0347452 A1
(43) Pub. Date: Nov. 30, 2017

(54) DISPLAY, MULTI-CIRCUIT BOARD AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventor: Xiaoyu HUANG, Shenzhen, Guangdong (CN)

(73) Assignee: SHENZHEN CHINA STAR OPTOELECTRONICS TECHNOLOGY CO., LTD., Shenzhen, Guangdong (CN)

(21) Appl. No.: 15/303,470

(22) PCT Filed: Aug. 17, 2016
(86) PCT No.: PCT/CN2016/095768

§ 371 Date: Oct. 11, 2016

(30) Foreign Application Priority Data
May 27, 2016 (CN) 2016103706557

(51) Int. Cl. H05K 1/14; H05K 3/36

(52) U.S. Cl. CPC H05K 1/14; H05K 3/36

(57) ABSTRACT

The present disclosure discloses a display, a multi-circuit board and a manufacturing method thereof, the multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF. The present disclosure also discloses a display and a manufacturing method of a multi-circuit board. Through the above way, the present disclosure can reduce the manufacturing cost of the multi-circuit board.

### BACKGROUND OF THE DISCLOSURE

### 1. Field of the Disclosure

The present disclosure relates to a circuit board technology field, and in particular to a display, a multi-circuit board and a manufacturing method thereof.

### 2. The Related Arts

Thin film transistor liquid crystal display, TFT-LCD, is one of the main breeds of the current flat panel display, which has become the important display platform of the modern IT, video products. The main driving principle of the TFT-LCD is that the system board connects the R/G/B compressed signal, the control signal and the power with each other through the connector on the PCB, after the data processed by the timing controller, TCON, IC on the PCB, through the connection between the PCB and the display region, thereby making the LCD obtained the required power and signals.

Along with the popularity of curved surface television, the application of curved surface of TFT-LCD becomes more and more, the curved panel may cause undesirable phenomena such as sealing or other of the components on the PCB. In order to avoid the undesirable phenomena caused by PCB bending, a solution is to divide the PCB into several segments, and then connecting each segment PCB through connectors and cables (FFC).

However, the costs of these connectors and cables are usually higher, not conducive to cost control.

Therefore, a display, a multi-circuit board and a manufacturing method thereof is required to solve the above technical issues.

### SUMMARY OF THE DISCLOSURE

The present disclosure is mainly to provide a display, a multi-circuit board and a manufacturing method in order to reduce the manufacturing cost of the multi-circuit board.

In order to solve the above technical issue, a technical solution adopted by the present disclosure is: to provide a multi-circuit board, the multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF.

Wherein the multi-circuit board further comprises a conductive colloid, both ends of the lead thin film being respectively connected with the first circuit board and the second circuit board through the conductive colloid.

Wherein the conductive colloid is an anisotropic conductive film, the anisotropic conductive film is respectively bounded with both ends of the lea thin film.

Wherein the anisotropic conductive film comprises a resin and conductive particles, the lead respectively transmits signals to the first circuit board and the second circuit board through the conductive particles.

Wherein the first circuit board is provided with at least one first pad, the second circuit board is provided with at least one second pad, the first pad being connected with the corresponded second pad through the lead.

In order to solve the above technical issue, another technical solution adopted by the present disclosure is: to provide a manufacturing method of a multi-circuit board, the manufacturing comprises: to encapsulate at least one lead between two thin films to form a lead thin film, and to provide at least a first circuit board and a second circuit board, wherein the thin film is a thin film substrate of chip on film, COF; to use the lead thin film to connect the first circuit board and the second circuit board, and to make the at least one lead to connect the first circuit board and the second circuit board.

Wherein the step of the step of encapsulating at least one lead between two thin films to form a lead thin film comprises: to press at least one lead between two thin films to form a lead thin film.

Wherein the step of using the lead thin film to connect the first circuit board and the second circuit board, and to make the at least one lead connect the first circuit board and the second circuit board comprises: to connect both ends of the lead thin film with the first circuit board and the second circuit board through a conductive colloid.

Wherein the step of connecting both ends of the lead thin film with the first circuit board and the second circuit board through a conductive colloid comprises: using an anisotropic conductive film to bounded both ends of the lead thin film with the first circuit board and the second circuit board.

In order to solve the above technical issue, the other technical solution adopted by the present disclosure is: to provide a display comprising a multi-circuit board, the multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF.

Wherein the multi-circuit board further comprises a conductive colloid, both ends of the lead thin film being respectively connected with the first circuit board and the second circuit board through the conductive colloid.

Wherein the conductive colloid is an anisotropic conductive film, the anisotropic conductive film is respectively bounded with both ends of the lea thin film.

Wherein the anisotropic conductive film comprises a resin and conductive particles, the lead respectively transmits signals to the first circuit board and the second circuit board through the conductive particles.

Wherein the first circuit board is provided with at least one first pad, the second circuit board is provided with at least one second pad, the first pad being connected with the corresponded second pad through the lead.

The benefit effect of the present disclosure is: to distinguish the prior art, through providing a multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF, using the film substrate of chip on film, COF, and a lead encapsulated therein to connect the first circuit board and the second circuit board, the present disclosure can save the costs of connectors and FFC flex cables, reducing the manufacturing cost of the multi-circuit board.

### BRIEF DESCRIPTION OF THE DRAWINGS

FIG. 1 is a structure diagram of the preferable embodiment of a multi-circuit board of the present disclosure;

FIG. 2 is a cross-sectional schematic diagram in A-A direction of a lead thin film of the present disclosure;

FIG. 3 is a cross-sectional schematic diagram in B-B direction of a lead thin film of the present disclosure;

FIG. 4 is a flow chart of the preferable embodiment of a manufacturing of the multi-circuit board of the present disclosure.

### DETAILED DESCRIPTION OF THE PREFERRED EMBODIMENTS

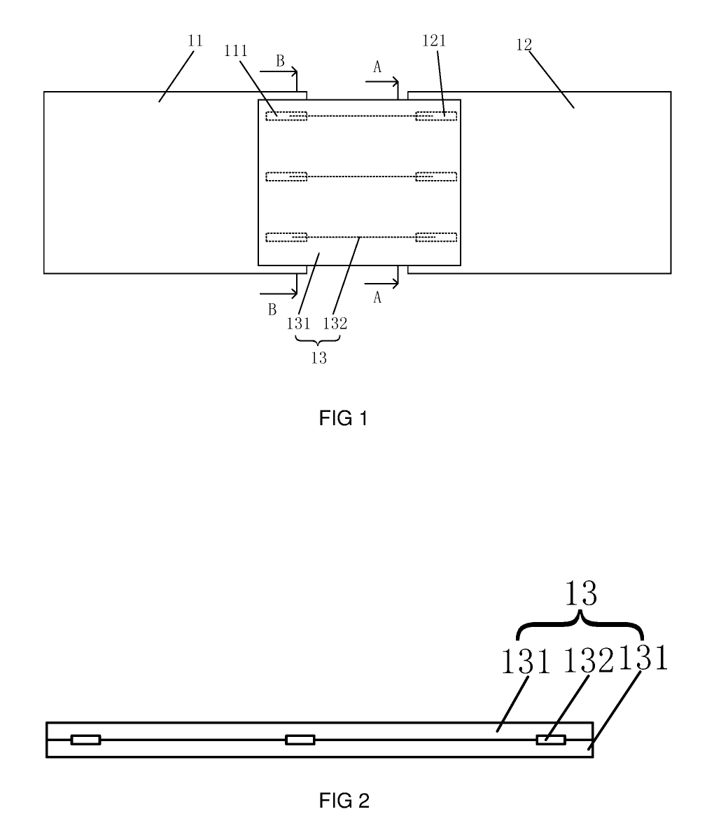

Refer to FIG. 1, FIG. 1 is a structure diagram of the preferable embodiment of a multi-circuit board of the present disclosure. In the present embodiment, the multi-circuit board comprises: a first circuit board 11, a second circuit board 12, a lead thin film 13 and a conductive colloid 14.

The lead thin film 13 is used to connect with the first circuit board 11 and the second circuit board 12.

Further refer to FIG. 2, FIG. 2 is a cross-sectional schematic diagram in A-A direction of a lead thin film of the present disclosure. The lead thin film 13 comprises two thin films 131 and at least one lead 132 encapsulated between two thin films 131, the first circuit board 11 and the second circuit board 12 are connected and conducted with each other through the at least one lead 132, the thin film 131 is a thin film substrate of chip on film, COF. As shown in FIG. 1 and FIG. 2, in the present embodiment, the lead 132 is preferably three, which can be other amounts in the other embodiments.

In the present embodiment, the multi-circuit board preferably comprises a first circuit board 11 and a second circuit board 12, which can also comprise a third circuit board (not shown), a fourth circuit board (not shown) and so on in other embodiments, or comprises more circuit boards, between these circuit boards can be connected by the similar conductive thin film. For example, when the multi-circuit comprises four circuit boards, the first circuit board 11 and the second circuit board 12 are connected and conducted with each other through the lead 132 of the lead thin film 13, the second circuit board and the third circuit board are connected and conducted with each other through the lead thin film, the third circuit board and the fourth circuit board are connected and conducted with each other through the lead thin film.

The first circuit board 11 is provided at least one first pad 111, the second circuit board 12 is provided at least one second pad 121, the first pad 111 is connected and conducted with the corresponded second pad 121 through the lead 132.

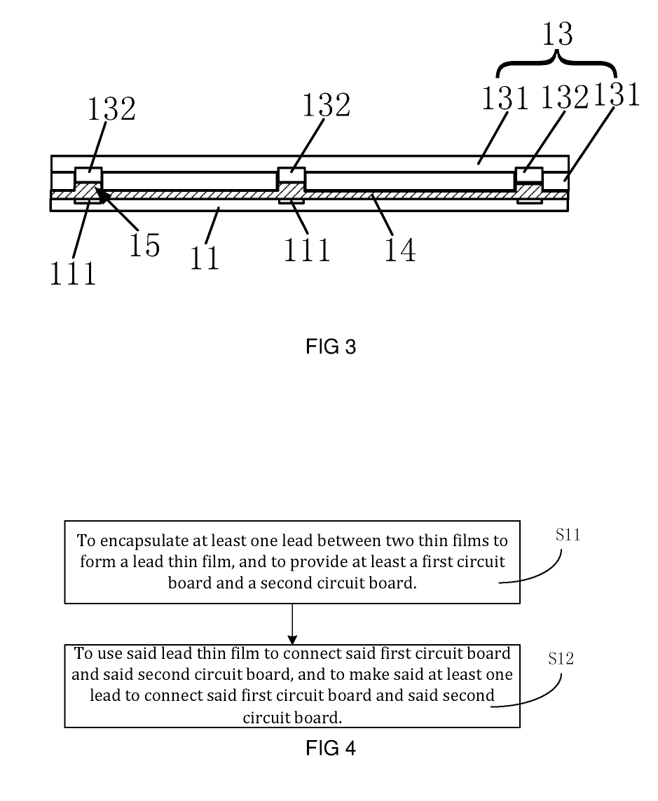

Further refer to FIG. 3, FIG. 3 is a cross-sectional schematic diagram in B-B direction of a lead thin film of the present disclosure. Preferably, both ends of the lead thin film 13 are connected with the first circuit board 11 and the second circuit board 12 through the conductive colloid 14. Preferably, the conductive colloid 14 is anisotropic conductive film 14, ACF, the anisotropic conductive film 14 is respectively bounded with both ends of the lead thin film 13. The lead 132 is conducted with the first pad 111 or the second pad 121 through the conductive colloid 14, meanwhile, both ends of the lead thin film 13 are respectively bounded with the first circuit board 11 and the second circuit board 12 through the conductive colloid 14, on one hand conducting the first circuit board 11 and the second circuit board 12, on the other hand the first circuit board 11 and the second circuit board 12 are flexibly connected with each other through the lead thin film 13. Take lead 132 and first pad 111 for example, the thin film 131 of which the lead thin film is near the first pad 111 is provided an opening 15 on the place where is corresponded to the first pad 111, the opening 15 exposes the lead 132, on the one hand the anisotropic conductive film 14 is partially contacted with the exposed lead 132, on the other hand the anisotropic conductive film 14 is contacted with the first pad 111, thereby conducting the lead 132 and the first pad. In the present disclosure, at the first, to clean the surface of the thin film 131 of which the lead thin film 13 is near the first pad 111, and then attaching through the anisotropic conductive film 14 and the first circuit board 11, and then carrying on the lamination. The circumstance of the lead 132 is similar to the second pad 121, there is no more description.

When the encapsulated leads 132 between the same two films 131 are plural arranged side by side, for example which are three arranged side by side in the present embodiment, since the anisotropic conductive film 14 is not conductive in parallel to the direction of the surface of the circuit board, which is only conductive in the direction perpendicular to the circuit board, therefore, between the plurality of leads 132 will not be short, and will not affect the conduction between the lead 132 and the first pad 111 as well as the second pad 121. In the other embodiments, the conductive colloid 14 also can be other conductive colloid 14.

Preferably, the anisotropic conductive film 14 comprises resin and conductive particles, the lead 132 respectively transmits signals to the first circuit board 11 and the second circuit board through the conductive particles.

Refer to FIG. 4, FIG. 4 is a flow chart of the preferable embodiment of a manufacturing of the multi-circuit board of the present disclosure. In the present embodiment, the manufacturing method of the multi-circuit board comprises the following steps:

Step S11: to encapsulate at least one lead between two thin films to form a lead thin film, and to provide at least a first circuit board and a second circuit board.

In the step S11, the thin film 131 is a thin film substrate of chip on film, COF. The step of the step of encapsulating at least one lead between two thin films to form a lead thin film comprises: to press at least one lead between two thin films to form a lead thin film.

Step S12: to use the lead thin film to connect the first circuit board and the second circuit board, and to make the at least one lead to connect the first circuit board and the second circuit board.

In the step S12, the step of using the lead thin film 13 to connect the first circuit board 11 and the second circuit board 12, and to make the at least one lead 132 connect the first circuit board 11 and the second circuit board 12 comprises: to connect both ends of the lead thin film 13 with the first circuit board 11 and the second circuit board 12 through a conductive colloid 14. Preferably, the step of connecting both ends of the lead thin film 13 with the first circuit board 11 and the second circuit board 12 through a conductive colloid 14 comprises: using an anisotropic conductive film 14 to bounded both ends of the lead thin film 13 with the first circuit board 11 and the second circuit board 12. The first circuit board 11 is provided with at least one first pad 111, the second circuit board 12 is provided with at least one second pad 121, the specific process of connecting both ends of the lead thin film 13 with the first circuit board 11 and the second circuit board 12 comprises: to clean the surface of lea thin film 13, the thin film 131 of which the lead thin film 13 is near to the first pad 111 and the second pad 121 respectively forms opening 15 on the place where is corresponded to the first pad 111 and the second pad 121, the opening 15 partially exposes the lead 132; attaching both ends of the lead thin film 13 on the first circuit board 11 and the second circuit board 12 through the anisotropic conductive film 14, laminating both ends of the lead thin film 13 with the first circuit board 11 and the second circuit board 12.

The present disclosure also provides a display comprising the multi-circuit board described by any one of above descriptions, preferably, the display is a curved surface display. It can be realized that the display does not only comprise the multi-circuit board, but also the other portion such as the display panel, the backlight module and so on. The multi-circuit board as described above is not only applied for curved surface display, but also the other displays. It is not limited by the present disclosure.

Through providing a multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF, using the film substrate of chip on film, COF, and a lead encapsulated therein to connect the first circuit board and the second circuit board, the present disclosure can save the costs of connectors and FFC flex cables, reducing the manufacturing cost of the multi-circuit board.

The preferred embodiments according to the present invention are mentioned above, which cannot be used to define the scope of the right of the present invention. Those variations of equivalent structure or equivalent process according to the present specification and the drawings or directly or indirectly applied in other areas of technology are considered encompassed in the scope of protection defined by the claims of the present invention.

What is claimed is:

1. A multi-circuit board, wherein the multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF.

2. The multi-circuit board as claimed in claim 1, wherein the multi-circuit board further comprises a conductive colloid, both ends of the lead thin film being respectively connected with the first circuit board and the second circuit board through the conductive colloid.

3. The multi-circuit board as claimed in claim 2, wherein the conductive colloid is an anisotropic conductive film, the anisotropic conductive film is respectively bounded with both ends of the lea thin film.

4. The multi-circuit board as claimed in claim 3, wherein the anisotropic conductive film comprises a resin and conductive particles, the lead respectively transmits signals to the first circuit board and the second circuit board through the conductive particles.

5. The multi-circuit board as claimed in claim 1, wherein the first circuit board is provided with at least one first pad, the second circuit board is provided with at least one second pad, the first pad being connected with the corresponded second pad through the lead.

6. A manufacturing method of a multi-circuit board, wherein the manufacturing comprises:
to encapsulate at least one lead between two thin films to form a lead thin film, and to provide at least a first circuit board and a second circuit board, wherein the thin film is a thin film substrate of chip on film, COF;
to use the lead thin film to connect the first circuit board and the second circuit board, and to make the at least one lead to connect the first circuit board and the second circuit board.

7. The manufacturing method as claimed in claim 6, wherein the step of encapsulating at least one lead between two thin films to form a lead thin film comprises:
to press at least one lead between two thin films to form a lead thin film.

8. The manufacturing method as claimed in claim 6, wherein the step of using the lead thin film to connect the first circuit board and the second circuit board, and to make the at least one lead connect the first circuit board and the second circuit board comprises:
to connect both ends of the lead thin film with the first circuit board and the second circuit board through a conductive colloid.

9. The manufacturing method as claimed in claim 8, wherein the step of connecting both ends of the lead thin film with the first circuit board and the second circuit board through a conductive colloid comprises:
using an anisotropic conductive film to bounded both ends of the lead thin film with the first circuit board and the second circuit board.

10. A display, wherein the display comprises a multi-circuit board, the multi-circuit board at least comprises a first circuit board, a second circuit board and a lead thin film used to connect with the first circuit board and the second circuit board, the lead thin film comprises two thin films and at least one lead encapsulated between the two thin films, the first circuit board and the second circuit board being connected with each other through at least one lead, the thin film is a thin film substrate of chip on film, COF.

11. The display as claimed in claim 10, wherein the multi-circuit board further comprises a conductive colloid, both ends of the lead thin film being respectively connected with the first circuit board and the second circuit board through the conductive colloid.

12. The display as claimed in claim 11, wherein the conductive colloid is an anisotropic conductive film, the anisotropic conductive film is respectively bounded with both ends of the lea thin film.

13. The display as claimed in claim 12, wherein the anisotropic conductive film comprises a resin and conductive particles, the lead respectively transmits signals to the first circuit board and the second circuit board through the conductive particles.

14. The display as claimed in claim 10, wherein the first circuit board is provided with at least one first pad, the second circuit board is provided with at least one second pad, the first pad being connected with the corresponded second pad through the lead.
